(19) United States
(12) Patent Application Publication
(10) Pub. No.: US 2024/0239684 A1
(43) Pub. Date: Jul. 18, 2024

(54) Ultra-Pure Molybdenum Dichloride Dioxide, Packaged Forms Thereof And Methods Of Preparing The Same

(71) Applicant: VERSUM MATERIALS US, LLC, Tempe, AZ (US)

(72) Inventors: Steven A. Krouse, Tamaqua, PA (US); SERGEI V. IVANOV, Schnecksville, PA (US); BRENT A. SPERLING, Center Valley, PA (US)

(21) Appl. No.: 18/565,326

(22) PCT Filed: May 20, 2022
(86) PCT No.: PCT/US22/72468

§ 371 Date: Nov. 29, 2023

Related U.S. Application Data
(60) Provisional application No. 63/195,691, filed on Jun. 1, 2021.

(51) Int. Cl. C01G 39/04

(52) U.S. Cl. CPC C01G 39/04; C01P 2002/82; C01P 2002/86; C01P 2006/10; C01P 2006/82

(57) ABSTRACT

The disclosed and claimed subject matter relates to ultra-pure molybdenum dichloride dioxide (i.e., MoO2Cl2) that is substantially free of moisture (H2O), hydrogen chloride (HCl) and/or residual protons. packaged forms of the same and a method of preparing the same.

### BACKGROUND

### Field

The disclosed and claimed subject matter relates to ultra-pure molybdenum dichloride dioxide (i.e., MoO₂Cl₂) that is substantially free of moisture (e.g., H₂O), hydrogen chloride (HCl) and/or residual protons, packaged forms of the same and a method of preparing the same.

### Related Art

Thin films, and in particular, thin metal-containing films, have a variety of important applications, such as in nanotechnology and the fabrication of semiconductor devices. Indeed, the semiconductor industry continues to drive deposition of continuous and conformal thin metal-containing films for advanced node applications. Examples of such applications include high-refractive index optical coatings, corrosion-protection coatings, photocatalytic self-cleaning glass coatings, biocompatible coatings, dielectric capacitor layers and gate dielectric insulating films in field-effect transistors (FETs), capacitor electrodes, gate electrodes, adhesive diffusion barriers, and integrated circuits. Metallic thin films and dielectric thin films are also used in microelectronics applications, such as the high-dielectric oxide for dynamic random-access memory (DRAM) applications and the ferroelectric perovskites used in infrared detectors and non-volatile ferroelectric random-access memories (NV-FeRAMs).

Such techniques include reactive sputtering, ion-assisted deposition, sol-gel deposition, chemical vapor deposition (CVD) (also known as metalorganic CVD or MOCVD), and atomic layer deposition (ALD) (also known as atomic layer epitaxy). CVD and atomic layer deposition ALD are used for fabricating conformal metal containing films on substrates, such as silicon, metal nitride, metal oxide and other metal-containing layers, using metal-containing precursors, and have the advantages of enhanced compositional control, high film uniformity, and effective control of doping.

In general, CVD and ALD both utilize a vapor of a volatile metal complex is introduced into a process chamber where it contacts the surface of a wafer whereupon a chemical reaction occurs that deposits a thin film of pure metal or a metal compound.

Conventional CVD is a chemical process whereby precursors are used to form a thin film on a substrate surface. In a typical CVD process, the precursors are passed over the surface of a substrate (e.g., a wafer) in a low pressure or ambient pressure reaction chamber. CVD occurs if the precursor reacts at the wafer surface either thermally or with a reagent added simultaneously into the process chamber and the film growth occurs in a steady state deposition. Put differently, the precursors react and/or decompose on the substrate surface creating a thin film of deposited material. Volatile by-products are removed by gas flow through the reaction chamber. CVD can be applied in a continuous or pulsed mode to achieve the desired film thickness. In some applications, however, the deposited film thickness can be difficult to control because it depends on coordination of many parameters such as temperature, pressure, gas flow volumes and uniformity, chemical depletion effects and time.

ALD is also a method for the deposition of thin films. It is a self-limiting, sequential, unique film growth technique based on surface reactions that can provide precise thickness control and deposit conformal thin films of materials provided by precursors onto surfaces substrates of varying compositions. In ALD, the precursors are separated during the reaction. The first precursor is passed over and chemisorbed onto the substrate surface producing a monolayer on the substrate surface. Any excess unreacted precursor is pumped out of or purged (with an inert gas) from the reaction chamber. A second precursor is then passed over the substrate surface and reacts with the first precursor, forming a second monolayer of film over the first-formed monolayer of film on the substrate surface. This cycle can then be repeated multiple times to build up the metal or metal compound to a desired thickness with atomic precision since the chemisorption of precursor and reagent are self-limiting. ALD can provide the deposition of ultra-thin yet continuous metal containing films with precise control of film thickness, excellent uniformity of film thickness and outstandingly conformal film growth to evenly coat deeply etched and highly convoluted structures such as interconnect vias and trenches. However. for tight control of the films thickness it is critical to avoid any uncontrolled reactions with potential impurities which can be present in precursors used in deposition process. Trace impurities may impact film nucleation, film growth, film etching and other elemental steps of deposition process.

For conventional chemical vapor deposition (CVD) process, the precursor and co-reactant are introduced into a deposition chamber via vapor phase to deposit a thick film on the substrate. On other hand, atomic layer deposition (ALD) or ALD-like process, the precursor and co-reactant are introduced into a deposition chamber sequentially, thus allowing a surface-controlled layer-by-layer deposition and importantly self-limiting surface reactions to achieve atomic-level growth of thin film. The key to a successful ALD deposition process is to employ a precursor to devise a reaction scheme consisting of a sequence of discrete, self-limiting adsorption and reaction steps. One great advantage of the ALD process is to provide much higher conformality for substrates having high aspect ratio such as >8 than CVD.

Various precursors may be used to form metal-containing thin films and a variety of deposition techniques can be employed. In his regard, molybdenum is highly promising conductive metal for variety of applications in semiconductor industry because molybdenum metal has low bulk resistivity. low electron mean free path and may not require a barrier between dielectric and molybdenum layer.

Molybdenum dichloride dioxide is an attractive precursor for deposition of molybdenum-containing films by chemical vapor deposition or atomic layer deposition processes because it has high vapor pressure, good thermal stability and can be reduced with hydrogen to form molybdenum films. See, e.g., U.S. Patent Application Publication Nos. 2019/027573, 2019/067003, 2019/067014, 2019/067016, 2019/067094 and 2019/67095. CVD using molybdenum dichloride dioxide provides molybdenum metal films with low oxygen content highly desirable by semiconducting industry. See K. A Gesheva, K. Seshan, B. O. Seraphin, Thin Solid Films, 79, 39-49 (1981).

Given its attractiveness for use in deposition processes, high purity molybdenum dichloride dioxide (MoO₂Cl₂) is desired for low resistivity molybdenum containing films for interconnects, vias and contacts between a first metal layer and the devices of silicon substrate, and for word line applications in DRAM and 3D NAND.

Molybdenum dichloride dioxide can be produced by several different routes. For example, MoO₂Cl₂ can be prepared by reacting MoO₂ with elemental chlorine at 150-350° C. See R. Graham and L. Hepler, Journal of Physical Chemistry, 723 (1959). The crude product was purified by ten sublimations. The authors observed that the material of different colors was obtained based on its purity and water contamination.

Another process proposed by Graham and Hepler involves reaction of MoO₃ with dry HCl but only molybdenum dichloride dioxide hydrate (MoO₂Cl₂ x H₂O or MoO(OH)₂Cl₂) is obtained by this route. The authors report that the hydrate can be sublimed without decomposition in the presence of excess of HCl.

Another process described in the literature involves the reaction of MoO₃ with NaCl to obtain MoO₂Cl₂ and Na₂MoO₄. See Zelikman et al., Zhurnal Obshchei Khimii, 24, 1916-20 (1954). However, this process requires relatively high temperature (500° C.) and produces significant amount of solid by-product Na₂MoO₄/Na₂Mo₂O₇. In addition, alkali metal halides contain residual moisture which may contaminate desired MoO₂Cl₂ during solid condensation step.

A common problem with all known MoO₂Cl₂ syntheses is their inability to provide MoO₂Cl₂ in sufficient purity for use in the electronics/semiconductor industry. In particular, the MoO₂Cl₂ provided by the known processes have high levels of hydrate (greater than 1 wt %) as well as other impurities. For example, residual molybdenum dichloride dioxide hydrate (i.e., MoO₂Cl₂ x H₂O or H₂MoO₃Cl₂) has a detrimental impact on precursor performance on ALD tool. The hydrate is relatively stable at room temperature and partially decomposes at the ampoule operating temperature to form MoO₃ and HCl. The formation of HCl gas during ampoule heating on ALD tool results in lower and unstable partial pressure of MoO₂Cl₂ during delivery. Thermal decomposition of the hydrate may also release moisture during heating resulting in highly corrosive “wet” HCl. Release of highly corrosive “wet” HCl may result in contamination of precursor vapor with metal contaminants, such as iron and chromium chlorides and oxychlorides.

Metallic contaminations on wafer surface are known to be a serious limiting factor to yield and reliability of CMOS based integrated circuits. Such contamination degrades the performance of the ultrathin SiO₂ gate dielectrics that form the heart of the individual transistors. Iron is one of the most troubling contaminants in the IC industry. Iron is a very common element in nature and is difficult to eliminate on a production line. Iron contamination was found to significantly decrease the breakdown voltage of gate oxides. The commonly reported mechanism for electrical field breakdown failure from iron contamination is the formation of iron precipitates at the SiO₂ interface, which frequently penetrate the silicon dioxide. When dissolved in silicon, iron forms deep levels which act to degrade junction device performance by the generation of carriers in any reverse-biased depletion region. In bipolar junction transistors, generation-recombination centers formed by dissolved iron generally increase the base currents, degrading the emitter efficiency and base transport factors. See Istratov et al., Appl. Phys. A, 70, 489 (2000). Thus, precursors with extremely low levels of iron contamination are highly desired. Purification methods to produce precursors such as MoO₂Cl₂ with extremely low iron contamination are also desired.

Given the above, there is a need for ultra-pure MoO₂Cl₂ that is free and/or substantially free of water and other proton-containing impurities (at the ppm or lower levels) for use in the electronics/semiconductor industry.

### SUMMARY

In one aspect, the disclosed and claimed subject matter relates to ultra-pure MoO₂Cl₂ that is free and/or substantially free of water and other impurities (at the ppm or lower levels) for use in the electronics/semiconductor industry.

In another aspect, the disclosed and claimed subject matter relates to a method of preparing ultra-pure MoO₂Cl₂ that is free and/or substantially free of water and other impurities (at the ppm or lower levels) for use in the electronics/semiconductor industry.

In another aspect, the disclosed and claimed subject matter relates to packaged forms of the ultra-pure MoO₂Cl₂ with high bulk density and high packing density. Such forms are provided by way of filling containers containing ultra-pure MoO₂Cl₂ that is free and/or substantially free of water and other impurities (at the ppm or lower levels) for use in the electronics/semiconductor industry.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates ¹H NMR spectra crude MoO₂Cl₂ containing 709 ppm of moisture (a) and ultra-pure MoO₂Cl₂ containing 126 ppm of H₂O (b). The amount of moisture was determined based on integration of ¹H NMR signals of protons in MoO₂Cl₂ and protons in internal standard;

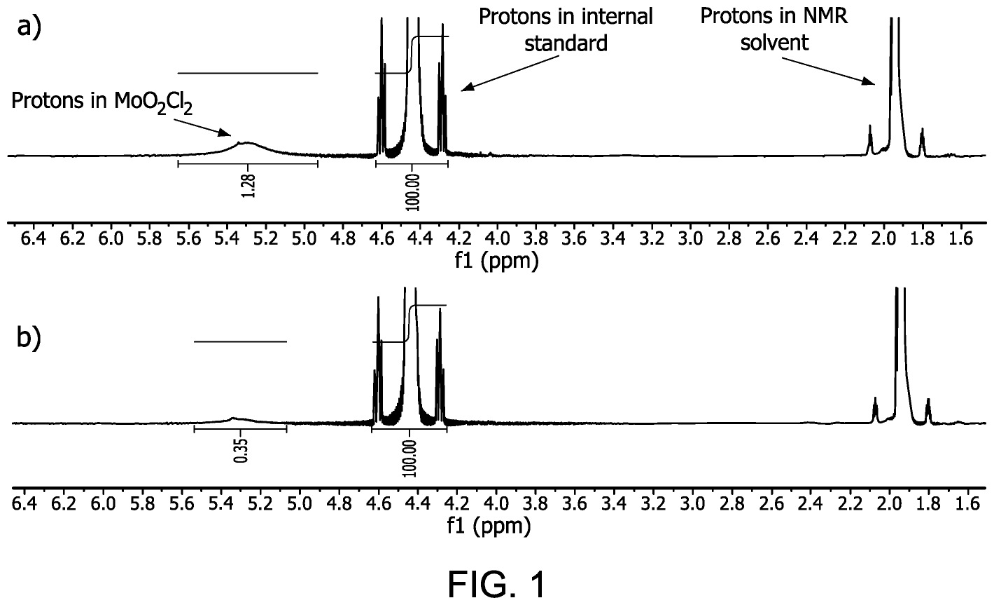

FIG. 2 illustrates ¹H NMR spectra of the NMR solvent spiked with internal standard (a) and ultra-pure MoO₂Cl₂ containing less than 20 ppm of H₂O (b). The amount of moisture was determined based on integration of ¹H NMR signals of protons in MoO₂Cl₂ and protons in internal standard using blank subtraction method;

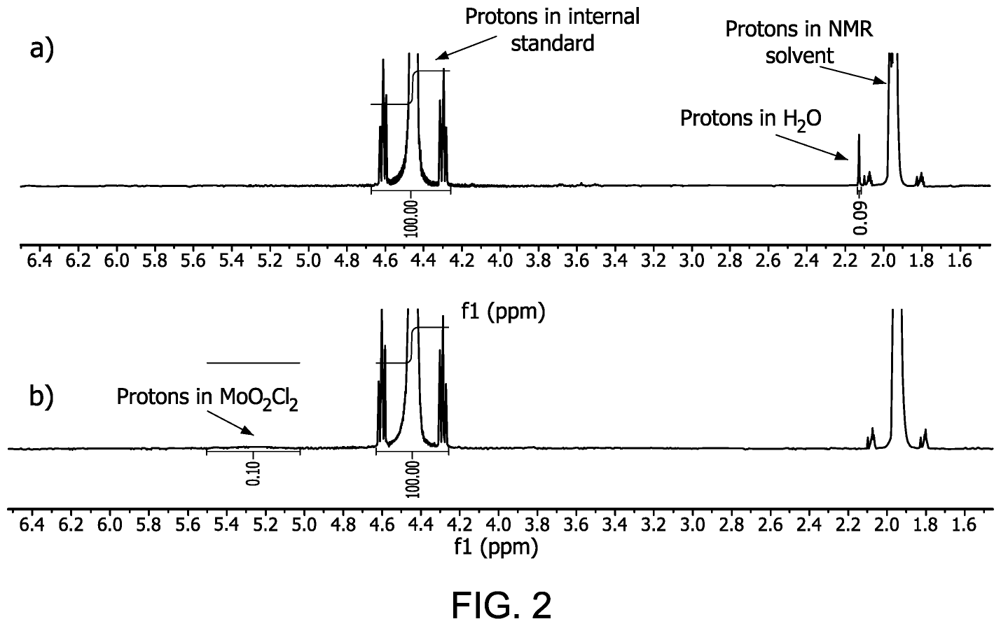

FIG. 3 illustrates the dependence of NMR signals of protons in MoO₂Cl₂ relative to the amount of moisture spiked in NMR solvent (water blank). The chart shows linear dependence of the NMR signal relative to the amount of water added to the solution of MoO₂Cl₂ in NMR solvent; and

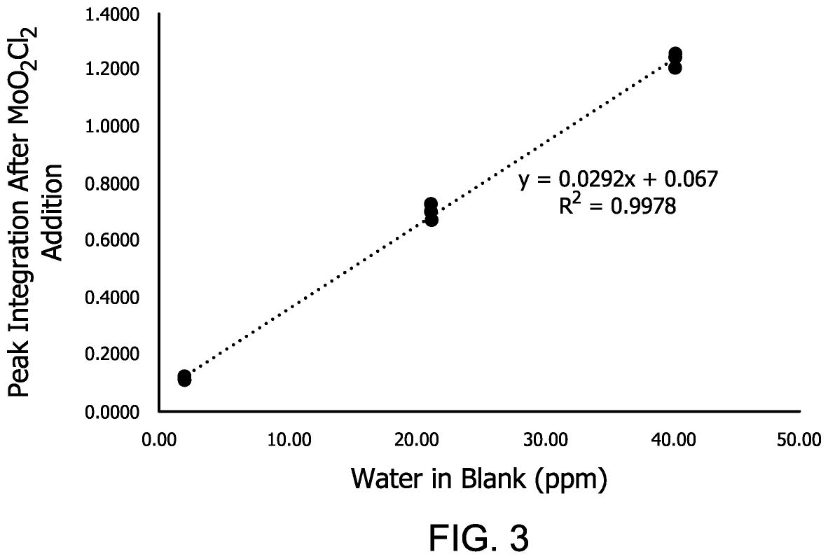

FIG. 4 illustrates the IR spectra of a vapor including MoO₂Cl₂ and residual HCl. The bottom spectrum illustrates the IR of a vapor at 190° C. including MoO₂Cl₂ where the absorbance of 2799 cm⁻¹ HCl peak is 86.3×10⁻⁴ AU/meter at 0.5 cm⁻¹ resolution. The middle spectrum illustrates the IR of a vapor at 190° C. including MoO₂Cl₂ where the absorbance of 2799 cm⁻¹ HCl peak is 7.4×10⁻⁴ AU. The top spectrum illustrates the IR of a vapor at 150° C. including MoO₂Cl₂ where the absorbance of 2799 cm⁻¹ HCl peak is 0.8×10⁻⁴ AU.

### DEFINITIONS

Unless otherwise stated, the following terms used in the specification and claims shall have the following meanings for this application.

For purposes of the disclosed and claimed subject matter, the numbering scheme for the Periodic Table Groups is according to the IUPAC Periodic Table of Elements.

The term “and/or” as used in a phrase such as “A and/or B” herein is intended to include “A and B.” “A or B,” “A” and “B.”

The terms “substituent.” “radical.” “group” and “moiety” may be used interchangeably.

As used herein, the terms “metal-containing complex” (or more simply, “complex”) and “precursor” are used interchangeably and refer to metal-containing molecule or compound which can be used to prepare a metal-containing film by a vapor deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film as more fully defined below, but also a film which includes a metal along with one or more elements, for example a metal oxide film, metal nitride film, metal silicide film, a metal carbide film and the like. As used herein, the terms “elemental metal film” and “pure metal film” are used interchangeably and refer to a film which consists of, or consists essentially of, pure metal. For example, the elemental metal film may include 100% pure metal or the elemental metal film may include at least about 70%, at least about 80%, at least about 90%, at least about 95%, at least about 96%, at least about 97%, at least about 98%, at least about 99%, at least about 99.9%, or at least about 99.99% pure metal along with one or more impurities. Unless context dictates otherwise, the term “metal film” shall be interpreted to mean an elemental metal film.

As used herein, the term “vapor deposition process” is used to refer to any type of vapor deposition technique, including but not limited to, CVD and ALD. In various embodiments, CVD may take the form of conventional (i.e., continuous flow) CVD, liquid injection CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al. J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds., The Royal Society of Chemistry: Cambridge, 2009; Chapter 1, pp. 1-36.

The term “about” or “approximately.” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

The disclosed and claimed precursors are preferably substantially free of proton source impurities. As used herein, the term “substantially free” as it relates to proton source impurities means amounts of any such impurity that would individually or collectively give rise to about 30 ppm or less of protons attributable from any such impurity individually as determined by ¹H NMR as described in more detail below.

The disclosed and claimed precursors are also preferably substantially free of metal ions or metals such as, Li⁺ (Li), Na⁺ (Na), K⁺ (K), Mg²⁺ (Mg), Ca²⁺ (Ca), Al³⁺ (Al), Fe²⁺ (Fe), Fe³⁺ (Fe), Ni²⁺ (Fc), Cr³⁺ (Cr), titanium (Ti), vanadium (V), manganese (Mn), cobalt (Co), nickel (Ni), copper (Cu) or zinc (Zn). These metal ions or metals are potentially present from the starting materials/reactor employed to synthesize the precursors. As used herein, the term “substantially free” as it relates to Li, Na, K, Mg, Ca, Al, Fe, Ni, Cr, Ti, V, Mn, Co, Ni, Cu or Zn means less than 5 ppm (by weight), preferably less than 3 ppm, and more preferably less than 1 ppm, and most preferably 0.1 ppm as measured by ICP-MS.

Halo or halide refers to a halogen, F, Cl, Br or I which is linked by one bond to an organic moicty. In some embodiments, the halogen is F. In other embodiments, the halogen is Cl.

Halogenated alkyl refers to a C₁ to C₂₀ alkyl which is fully or partially halogenated.

Perfluoroalkyl refers to a linear, cyclic or branched saturated alkyl group as defined above in which the hydrogens have all been replaced by fluorine (e.g., trifluoromethyl, perfluorocthyl, perfluoropropyl, perfluorobutyl, perfluoroisopropyl, perfluorocyclohexyl and the like).

The MoO₂Cl₂ is substantially free of organic impurities which are from either starting materials employed during synthesis or by-products generated during synthesis. Examples include, but not limited to, alkanes, alkenes, alkynes, dienes, ethers, esters, acetates, amines, ketones, amides, aromatic compounds. As used herein, the term “free of” organic impurities, means 1000 ppm or less as measured by GC, preferably 500 ppm or less (by weight) as measured by GC, most preferably 100 ppm or less (by weight) as measured by GC or other analytical method for assay. Importantly the precursors preferably have purity of 98 wt % or higher, more preferably 99 wt % or higher as measured by GC when used as precursor to deposit the ruthenium-containing films.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

As noted above, the disclosed and claimed subject matter relates to ultra-pure MoO₂Cl₂ that is free and/or substantially free of water and other impurities (at the ppm or lower levels) for use in the electronics/semiconductor industry.

In another aspect, the disclosed and claimed subject matter relates to a method of preparing ultra-pure MoO₂Cl₂ that is free and/or substantially free of water and other impurities (at the ppm or lower levels) for use in the electronics/semiconductor industry.

In another aspect, the disclosed and claimed subject matter relates to packaged forms of the ultra-pure MoO₂Cl₂ with high bulk density and high packing density. Such forms are provided by way of filling containers containing ultra-pure MoO₂Cl₂ that is free and/or substantially free of water and other impurities (at the ppm or lower levels) for use in the electronics/semiconductor industry.

The ultra-pure MoO₂Cl₂ can be transferred into another vessel for bulk delivery to a tool for deposition of molybdenum containing films. Additionally, the ultra-pure MoO₂Cl₂ shows substantially lower corrosion rate in steel (e.g., SS316) and alloys when used as a vapor.

Further embodiments and aspect of ultra-pure MoO₂Cl₂, methods of its preparation and containers for the same are described below.

### I. Ultra-Pure MoO₂Cl₂

### A. Impurities

The disclosed and claimed subject matter includes ultra-pure MoO₂Cl₂ free of or substantially free of residual H₂O, HCl, other impurities and other proton sources which are undesirable for use of this precursor in deposition of molybdenum-containing films. In this regard, the disclosed and claimed subject matter further provides an analytical method to detect small amount of residual MoO₂Cl₂ hydrate other proton source impurities in MoO₂Cl₂. While crystal structures of MoO₂Cl₂ and its hydrate are known, see, e.g., L. O. Atovmyan, Z. G. Aliev and B. M. Tarakanov, J. of Structural Chemistry, 9, 985-986 (1969) and Von F. A. Schroeder and A. N. Christensen, Z. Anorg. Allg. Chem., 392, 107-123 (1972), the detection limit of X-ray powder diffraction analytical methods is insufficient to detect low concentrations of MoO₂Cl₂ hydrate and other proton source impurities in MoO₂Cl₂. Thus, a more sensitive analytical method for measuring residual moisture, other impurities (e.g., MoO₂Cl₂ hydrate) and other proton source impurity (e.g., HCl) in MoO₂Cl₂ is needed.

Regardless of detection method, there has been no reported synthesis or availability of ultra-pure MoO₂Cl₂ as described herein because until now such a material was unknown and unobtainable in the art. As those skilled in the art will recognize, the primary proton impurity sources in MoO₂Cl₂ are derived from the reaction of MoO₂Cl₂ with water as follows:

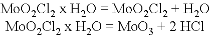

where the components of those reaction have the following molecular weights (MW) and maximum relative amounts produced by decomposition of MoO₂Cl₂ hydrate:

| | | Relative |
|---|---|---|
| | | Mass |
| Compound | MW | (g) |
| MoO₂Cl2 x H₂O | 216.86 | 1000.0 |
| MoO₂Cl₂ | 198.84 | 916.9 |
| MoO₃ | 143.94 | 663.7 |
| HCl | 36.46 | 336.3 |
| H₂O | 18.02 | 83.1 |

Based on the above values, it is possible to level of calculate, based on ¹H NMR analysis, maximum total proton source impurities at the ppm level. Unless specified otherwise ppm means “parts per million weight” (i.e., “ppmw”).

| MoO₂Cl₂ x H₂O | H₂O | H₂O | HCl | H | MoO₂Cl₂ |
|---|---|---|---|---|---|
| (wt %) | (wt %) | (ppm) | (ppm) | (ppm) | Purity |
| 0.015 | 0.001 | 12.5 | 50.7 | 1.4 | Ultra- |
| 0.030 | 0.003 | 25.0 | 101.4 | 2.8 | Pure |
| 0.060 | 0.005 | 50.0 | 202.9 | 5.6 | |
| 0.090 | 0.008 | 75.0 | 304.3 | 8.3 | |
| 0.121 | 0.010 | 100.0 | 405.7 | 11.1 | |
| 0.151 | 0.013 | 125.1 | 507.2 | 13.9 | |
| 0.301 | 0.025 | 250.1 | 1014.3 | 27.8 | |
| 0.452 | 0.038 | 375.2 | 1521.5 | 41.7 | Not |
| 0.603 | 0.050 | 500.2 | 2028.6 | 55.6 | Reported |
| 0.753 | 0.063 | 625.3 | 2535.8 | 69.5 | |
| 0.904 | 0.075 | 750.3 | 3042.9 | 83.4 | |
| 1.055 | 0.088 | 875.4 | 3550.1 | 97.3 | Currently |
| 1.205 | 0.100 | 1000.4 | 4057.2 | 111.2 | Reported |
| 1.356 | 0.113 | 1125.5 | 4564.4 | 125.1 | Purity |
| 1.507 | 0.125 | 1250.5 | 5071.6 | 138.9 | Standard |

The disclosed and claimed subject matter provides ultra-pure MoO₂Cl₂ down to sub-2 ppm levels of proton impurities. This represents up to nearly a 100-fold increase in purity compared to known “pure” MoO₂Cl₂ and/or provided by processes for preparing MoO₂Cl₂.

### 1. Total Proton

As noted above, the ultra-pure MoO₂Cl₂ of the disclosed and claimed subject matter is free or substantially free of protons from physiosorbed or chemisorbed moisture and detectable by the ¹H NMR technique described below. Such protons include those from MoO₂Cl₂ hydrate, HCl, molybdic acid, etc.

In one embodiment, the ultra-pure MoO₂Cl₂ has less than about 50 ppm of protons in the physiosorbed or chemisorbed state as measured by ¹H NMR. In one embodiment, the ultra-pure MoO₂Cl₂ has less than about 40 ppm of protons in the physiosorbed or chemisorbed state as measured by ¹H NMR. In one embodiment, the ultra-pure MoO₂Cl₂ has less than about 30 ppm of protons in the physiosorbed or chemisorbed state as measured by ¹H NMR. In one embodiment, the ultra-pure MoO₂Cl₂ has less than about 25 ppm of protons in the physiosorbed or chemisorbed state as measured by ¹H NMR. In one embodiment, the ultra-pure MoO₂Cl₂ has less than about 20 ppm of protons in the physiosorbed or chemisorbed state as measured by ¹H NMR. In one embodiment, the ultra-pure MoO₂Cl₂ has less than about 15 ppm of protons in the physiosorbed or chemisorbed state as measured by ¹H NMR. In one embodiment, the ultra-pure MoO₂Cl₂ has less than about 10 ppm of protons in the physiosorbed or chemisorbed state as measured by ¹H NMR. In one embodiment, the ultra-pure MoO₂Cl₂ has less than about 9 ppm of protons in the physiosorbed or chemisorbed state as measured by ¹H NMR. In one embodiment, the ultra-pure MoO₂Cl₂ has less than about 8 ppm of protons in the physiosorbed or chemisorbed state as measured by ¹H NMR. In one embodiment, the ultra-pure MoO₂Cl₂ has less than about 7 ppm of protons in the physiosorbed or chemisorbed state as measured by ¹H NMR. In one embodiment, the ultra-pure MoO₂Cl₂ has less than about 6 ppm of protons in the physiosorbed or chemisorbed state as measured by ¹H NMR. In one embodiment, the ultra-pure MoO₂Cl₂ has less than about 5 ppm of protons in the physiosorbed or chemisorbed state as measured by ¹H NMR. In one embodiment, the ultra-pure MoO₂Cl₂ has less than about 4 ppm of protons in the physiosorbed or chemisorbed state as measured by ¹H NMR. In one embodiment, the ultra-pure MoO₂Cl₂ has less than about 3 ppm of protons in the physiosorbed or chemisorbed state as measured by ¹H NMR. In one embodiment, the ultra-pure MoO₂Cl₂ has less than about 2.5 ppm of protons in the physiosorbed or chemisorbed state as measured by ¹H NMR. In one embodiment, the ultra-pure MoO₂Cl₂ has less than about 2 ppm of protons in the physiosorbed or chemisorbed state as measured by ¹H NMR. In one embodiment, the ultra-pure MoO₂Cl₂ has less than about 1.5 ppm of protons in the physiosorbed or chemisorbed state as measured by ¹H NMR. In one embodiment, the ultra-pure MoO₂Cl₂ has less than about 1 ppm of protons in the physiosorbed or chemisorbed state as measured by ¹H NMR.

In one embodiment, the ultra-pure MoO₂Cl₂ is free of detectable protons as measured by ¹H NMR. In one embodiment, the ultra-pure MoO₂Cl₂ is free of protons as measured by ¹H NMR

### 2. Moisture (H₂O)

As noted above, the ultra-pure MoO₂Cl₂ of the disclosed and claimed subject matter is free or substantially free of residual H₂O as measured by ¹H NMR (as described herein).

In one embodiment, the residual total content of H₂O as measured by ¹H NMR is less than about 250 ppm in the physiosorbed or chemisorbed state. In one embodiment, the residual total content of H₂O as measured by ¹H NMR is less than about 200 ppm in the physiosorbed or chemisorbed state. In one embodiment, the residual total content of H₂O as measured by ¹H NMR is less than about 150 ppm in the physiosorbed or chemisorbed state. In one embodiment, the residual total content of H₂O as measured by ¹H NMR is less than about 100 ppm in the physiosorbed or chemisorbed state. In one embodiment, the residual total content of H₂O as measured by ¹H NMR is less than about 75 ppm in the physiosorbed or chemisorbed state. In one embodiment, the residual total content of H₂O as measured by ¹H NMR is less than about 50 ppm in the physiosorbed or chemisorbed state. In one embodiment, the residual total content of H₂O as measured by ¹H NMR is less than about 25 ppm in the physiosorbed or chemisorbed state. In one embodiment, the residual total content of H₂O as measured by ¹H NMR is less than about 20 ppm in the physiosorbed or chemisorbed state. In one embodiment, the residual total content of H₂O as measured by ¹H NMR is less than about 15 ppm in the physiosorbed or chemisorbed state. In one embodiment, the residual total content of H₂O as measured by ¹H NMR is less than about 12.5 ppm in the physiosorbed or chemisorbed state. In one embodiment, the residual total content of H₂O as measured by ¹H NMR is less than about 10 ppm in the physiosorbed or chemisorbed state.

In one embodiment, the residual total content of H₂O as measured by ¹H NMR is less than about 0.030 wt % in the physiosorbed or chemisorbed state. In one embodiment, the residual total content of H₂O as determined by ¹H NMR is less than about 0.025 wt % in the physiosorbed or chemisorbed state. In one embodiment, the residual total content of H₂O as measured by ¹H NMR is less than about 0.020 wt % in the physiosorbed or chemisorbed state. In one embodiment, the residual total content of H₂O as measured by ¹H NMR is less than about 0.015 wt % in the physiosorbed or chemisorbed state. In one embodiment, the residual total content of H₂O as measured by ¹H NMR is less than about 0.014 wt % in the physiosorbed or chemisorbed state. In one embodiment, the residual total content of H₂O as measured by ¹H NMR is less than about 0.013 wt % in the physiosorbed or chemisorbed state. In one embodiment, the residual total content of H₂O as measured by ¹H NMR is less than about 0.012 wt % in the physiosorbed or chemisorbed state. In one embodiment, the residual total content of H₂O as measured by ¹H NMR is less than about 0.011 wt % in the physiosorbed or chemisorbed state. In one embodiment, the residual total content of H₂O as measured by ¹H NMR is less than about 0.010 wt % in the physiosorbed or chemisorbed state. In one embodiment, the residual total content of H₂O as measured by ¹H NMR is less than about 0.009 wt % in the physiosorbed or chemisorbed state. In one embodiment, the residual total content of H₂O as measured by ¹H NMR is less than about 0.008 wt % in the physiosorbed or chemisorbed state. In one embodiment, the residual total content of H₂O as measured by ¹H NMR is less than about 0.007 wt % in the physiosorbed or chemisorbed state. In one embodiment, the residual total content of H₂O as measured by ¹H NMR is less than about 0.006 wt % in the physiosorbed or chemisorbed state. In one embodiment, the residual total content of H₂O as measured by ¹H NMR is less than about 0.005 wt % in the physiosorbed or chemisorbed state. In one embodiment, the residual total content of H₂O as measured by ¹H NMR is less than about 0.004 wt % in the physiosorbed or chemisorbed state. In one embodiment, the residual total content of H₂O as measured by ¹H NMR is less than about 0.003 wt % in the physiosorbed or chemisorbed state. In one embodiment, the residual total content of H₂O as measured by ¹H NMR is less than about 0.002 wt % in the physiosorbed or chemisorbed state. In one embodiment, the residual total content of H₂O as measured by ¹H NMR is less than about 0.001 wt % in the physiosorbed or chemisorbed state.

In one embodiment, the ultra-pure MoO₂Cl₂ is free of detectable H₂O as measured by ¹H NMR. In one embodiment, the ultra-pure MoO₂Cl₂ is free of H₂O as measured by ¹H NMR.

### 3. Hydrochloric Acid (HCl)

### A. HCl in the Physiosorbed or Chemisorbed State

In one embodiment, the ultra-pure MoO₂Cl₂ of the disclosed and claimed subject matter is free or substantially free of residual HCl as measured by ¹H NMR (as described herein) in the physiosorbed or chemisorbed state.

In one embodiment, the residual total content of HCl as measured by ¹H NMR is less than about 1000 ppm in the physiosorbed or chemisorbed state. In one embodiment, the residual total content of HCl as measured by ¹H NMR is less than about 900 ppm in the physiosorbed or chemisorbed state. In one embodiment, the residual total content of HCl as measured by ¹H NMR is less than about 800 ppm in the physiosorbed or chemisorbed state. In one embodiment, the residual total content of HCl as measured by ¹H NMR is less than about 700 ppm in the physiosorbed or chemisorbed state. In one embodiment, the residual total content of HCl as measured by ¹H NMR is less than about 600 ppm in the physiosorbed or chemisorbed state. In one embodiment, the residual total content of HCl as measured by ¹H NMR is less than about 550 ppm in the physiosorbed or chemisorbed state. In one embodiment, the residual total content of HCl as measured by ¹H NMR is less than about 500 ppm in the physiosorbed or chemisorbed state. In one embodiment, the residual total content of HCl as measured by ¹H NMR is less than about 450 ppm in the physiosorbed or chemisorbed state. In one embodiment, the residual total content of HCl as measured by ¹H NMR is less than about 400 ppm in the physiosorbed or chemisorbed state. In one embodiment, the residual total content of HCl as measured by ¹H NMR is less than about 350 ppm in the physiosorbed or chemisorbed state. In one embodiment, the residual total content of HCl as measured by ¹H NMR is less than about 300 ppm in the physiosorbed or chemisorbed state. In one embodiment, the residual total content of HCl as measured by ¹H NMR is less than about 250 ppm in the physiosorbed or chemisorbed state. In one embodiment, the residual total content of HCl as measured by ¹H NMR is less than about 200 ppm in the physiosorbed or chemisorbed state. In one embodiment, the residual total content of HCl as measured by ¹H NMR is less than about 150 ppm in the physiosorbed or chemisorbed state. In one embodiment, the residual total content of HCl as measured by ¹H NMR is less than about 125 ppm in the physiosorbed or chemisorbed state. In one embodiment, the residual total content of HCl as measured by ¹H NMR is less than about 90 ppm in the physiosorbed or chemisorbed state. In one embodiment, the residual total content of HCl as measured by ¹H NMR is less than about 80 ppm in the physiosorbed or chemisorbed state. In one embodiment, the residual total content of HCl as measured by ¹H NMR is less than about 70 ppm in the physiosorbed or chemisorbed state. In one embodiment, the residual total content of HCl as measured by ¹H NMR is less than about 60 ppm in the physiosorbed or chemisorbed state. In one embodiment, the residual total content of HCl as measured by ¹H NMR is less than about 50 ppm in the physiosorbed or chemisorbed state. In one embodiment, the residual total content of HCl as measured by ¹H NMR is less than about 40 ppm in the physiosorbed or chemisorbed state.

In one embodiment, the ultra-pure MoO₂Cl₂ is free of detectable HCl as measured by ¹H NMR. In one embodiment, the ultra-pure MoO₂Cl₂ is free of HCl as measured by ¹H NMR.

### B. HCl in the Vapor State

In one embodiment, the ultra-pure MoO₂Cl₂ of the disclosed and claimed subject matter is free or substantially free of residual HCl as measured by infrared spectroscopy (IR) or tunable diode laser absorption spectroscopy (TDLAS). In one embodiment, for example, the ultra-pure MoO₂Cl₂ vapor is free of HCl as measured by Fourier transform infrared spectroscopy (FT-IR).

In one embodiment, the ultra-pure MoO₂Cl₂ vapor produced from ultra-pure solid MoO₂Cl₂ prepared by the disclosed and claimed subject matter is free of detectable HCl as measured by FT-IR peaks between 2600 and 3100 cm⁻¹ attributed to gaseous HCl. In one embodiment HCl peak at 2799 cm⁻¹ is used to quantify the amount of HCl in MoO₂Cl₂ vapor.

In one embodiment, the absorbance of 2799 cm⁻¹ HCl peak in MoO₂Cl₂ vapor is less than 100×10⁻⁴ Absorbance Units/meter at 0.5 cm⁻¹ resolution. In one embodiment, the absorbance of 2799 cm⁻¹ HCl peak in MoO₂Cl₂ vapor is less than 50×10⁻⁴ Absorbance Units/meter at 0.5 cm⁻¹ resolution. In one embodiment, the absorbance of 2799 cm⁻¹ HCl peak in MoO₂Cl₂ vapor is less than 10×10⁻⁴ Absorbance Units/meter at 0.5 cm⁻¹ resolution. In one embodiment, the absorbance of 2799 cm⁻¹ HCl peak in MoO₂Cl₂ vapor is less than 5×10⁻⁴ Absorbance Units/meter at 0.5 cm⁻¹ resolution. In one embodiment, the absorbance of 2799 cm⁻¹ HCl peak in MoO₂Cl₂ vapor is less than 1×10⁻⁴ Absorbance Units/meter at 0.5 cm⁻¹ resolution.

In one embodiment, the ultra-pure MoO₂Cl₂ is free of detectable HCl as measured by IR. In one embodiment, the ultra-pure MoO₂Cl₂ is free of HCl as measured by IR.

In one embodiment, the disclosed and claimed subject matter includes a vapor (i.e., gas) that includes, consist essentially of or consists of MoO₂Cl₂ where the vapor is free or substantially free of gaseous HCl. In one embodiment, the concentration of gaseous HCl in the MoO₂Cl₂ vapor is less than 300 ppm volume as measured by IR. In one embodiment, the concentration of gaseous HCl in the MoO₂Cl₂ vapor is less than 150 ppm volume as measured by IR. In one embodiment, the concentration of gaseous HCl in the MoO₂Cl₂ vapor is less than 100 ppm volume as measured by IR. In one embodiment, the concentration of gaseous HCl in the MoO₂Cl₂ vapor is less than 60 ppm volume as measured by IR. In one embodiment, the concentration of gaseous HCl in the MoO₂Cl₂ vapor is less than 30 ppm volume as measured by IR. In one embodiment, the concentration of gaseous HCl in the MoO₂Cl₂ vapor is less than 15 ppm volume as measured by IR. In one embodiment, the concentration of gaseous HCl in MoO₂Cl₂ vapor is less than 3 ppm volume as measured by IR.

4. MoO₂Cl₂ Hydrate

As noted above, the ultra-pure MoO₂Cl₂ of the disclosed and claimed subject matter is free or substantially free of residual MoO₂Cl₂ hydrate as measured by ¹H NMR (as described herein). Commonly used chemical formulas to describe the hydrate as MoO₂Cl₂ x H₂O and MoO(OH)₂Cl₂, H₂MoO₃Cl₃.

In one embodiment, the residual total content of MoO₂Cl₂x H₂O as measured by ¹H NMR is less than about 0.30 wt % in the physiosorbed or chemisorbed state. In one embodiment, the residual total content of MoO₂Cl₂ x H₂O as measured by ¹H NMR is less than about 0.25 wt % in the physiosorbed or chemisorbed state. In one embodiment, the residual total content of MoO₂Cl₂ x H₂O as measured by ¹H NMR is less than about 0.20 wt % in the physiosorbed or chemisorbed state. In one embodiment, the residual total content of MoO₂Cl₂ x H₂O as measured by ¹H NMR is less than about 0.15 wt % in the physiosorbed or chemisorbed state. In one embodiment, the residual total content of MoO₂Cl₂ x H₂O as measured by ¹H NMR is less than about 0.14 wt % in the physiosorbed or chemisorbed state. In one embodiment, the residual total content of MoO₂Cl₂ x H₂O as measured by ¹H NMR is less than about 0.13 wt % in the physiosorbed or chemisorbed state. In one embodiment, the residual total content of MoO₂Cl₂ x H₂O as measured by ¹H NMR is less than about 0.12 wt % in the physiosorbed or chemisorbed state. In one embodiment, the residual total content of MoO₂Cl₂ x H₂O as measured by ¹H NMR is less than about 0.11 wt % in the physiosorbed or chemisorbed state. In one embodiment, the residual total content of MoO₂Cl₂ x H₂O as measured by ¹H NMR is less than about 0.10 wt % in the physiosorbed or chemisorbed state. In one embodiment, the residual total content of MoO₂Cl₂ x H₂O as measured by ¹H NMR is less than about 0.09 wt % in the physiosorbed or chemisorbed state. In one embodiment, the residual total content of MoO₂Cl₂ x H₂O as measured by ¹H NMR is less than about 0.08 wt % in the physiosorbed or chemisorbed state. In one embodiment, the residual total content of MoO₂Cl₂ x H₂O as measured by ¹H NMR is less than about 0.07 wt % in the physiosorbed or chemisorbed state. In one embodiment, the residual total content of MoO₂Cl₂ x H₂O as measured by ¹H NMR is less than about 0.06 wt % in the physiosorbed or chemisorbed state. In one embodiment, the residual total content of MoO₂Cl₂ x H₂O as measured by ¹H NMR is less than about 0.05 wt % in the physiosorbed or chemisorbed state. In one embodiment, the residual total content of MoO₂Cl₂ x H₂O as measured by ¹H NMR is less than about 0.04 wt % in the physiosorbed or chemisorbed state. In one embodiment, the residual total content of MoO₂Cl₂ x H₂O as measured by ¹H NMR is less than about 0.03 wt % in the physiosorbed or chemisorbed state. In one embodiment, the residual total content of MoO₂Cl₂ x H₂O as measured by ¹H NMR is less than about 0.02 wt % in the physiosorbed or chemisorbed state. In one embodiment, the residual total content of MoO₂Cl₂ x H₂O as measured by ¹H NMR is less than about 0.015 wt % in the physiosorbed or chemisorbed state. In one embodiment, the residual total content of MoO₂Cl₂ x H₂O as measured by ¹H NMR is less than about 0.01 wt % in the physiosorbed or chemisorbed state.

In one embodiment, the ultra-pure MoO₂Cl₂ is free of detectable MoO₂Cl₂ x H₂O as measured by ¹H NMR. In one embodiment, the ultra-pure MoO₂Cl₂ is free of MoO₂Cl₂ x H₂O as measured by ¹H NMR.

### 4. MoO₃

As noted above, the ultra-pure MoO₂Cl₂ of the disclosed and claimed subject matter is free or substantially free of residual MoO₃. In one embodiment, the residual total content of MoO₃ is less than about 0.20 wt % in the physiosorbed or chemisorbed state. In one embodiment, the residual total content of MoO₃ is less than about 0.15 wt % in the physiosorbed or chemisorbed state. In one embodiment, the residual total content of MoO₃ is less than about 0.14 wt % in the physiosorbed or chemisorbed state. In one embodiment, the residual total content of MoO₃ is less than about 0.13 wt % in the physiosorbed or chemisorbed state. In one embodiment, the residual total content of MoO₃ is less than about 0.12 wt % in the physiosorbed or chemisorbed state. In one embodiment, the residual total content of MoO₃ is less than about 0.11 wt % in the physiosorbed or chemisorbed state. In one embodiment, the residual total content of MoO₃ is less than about 0.10 wt % in the physiosorbed or chemisorbed state.

### B. Bulk Density

As noted above, the ultra-pure MoO₂Cl₂ of the disclosed and claimed subject matter exhibits unexpectedly high bulk densities approaching 3.0 g/cm³ and above. Bulk density of MoO₂Cl₂ is defined as the mass of MoO₂Cl₂ sample per volume occupied by the sample, expressed in g/cm³. MoO₂Cl₂ is typically manufactured in a powder or crystal form with low bulk density, less than 1 g/cm³, and high surface area. For example, the bulk densities of the disclosed and claimed ultra-pure MoO₂Cl₂ more than doubles the previously reported bulk density values for MoO₂Cl₂ described in WO Publication No. 2020/021786 (0.8-1.2 g/cm³).

In one embodiment, the ultra-pure MoO₂Cl₂ has a bulk density of greater than about 2.0 g/cm³. In one embodiment, the ultra-pure MoO₂Cl₂ has a bulk density of greater than about 2.1 g/cm³. In one embodiment, the ultra-pure MoO₂Cl₂ has a bulk density of greater than about 2.2 g/cm³. In one embodiment, the ultra-pure MoO₂Cl₂ has a bulk density of greater than about 2.3 g/cm³. In one embodiment, the ultra-pure MoO₂Cl₂ has a bulk density of greater than about 2.4 g/cm³. In one embodiment, the ultra-pure MoO₂Cl₂ has a bulk density of greater than about 2.5 g/cm³. In one embodiment, the ultra-pure MoO₂Cl₂ has a bulk density of greater than about 2.6 g/cm³. In one embodiment, the ultra-pure MoO₂Cl₂ has a bulk density of greater than about 2.7 g/cm³. In one embodiment, the ultra-pure MoO₂Cl₂ has a bulk density of greater than about 2.8 g/cm³. In one embodiment, the ultra-pure MoO₂Cl₂ has a bulk density of greater than about 2.9 g/cm³. In one embodiment, the ultra-pure MoO₂Cl₂ has a bulk density of greater than about 3.0 g/cm³.

### II. Method of Preparing Ultra-Pure MoO₂Cl₂

As noted above, the disclosed and claimed subject matter also relates to a method of preparing ultra-pure MoO₂Cl₂ in which Low purity molybdenum dichloride dioxide (e.g., that includes molybdenum dichloride dioxide hydrate, H₂MoO₃Cl₂) is heated above its melting point in a sealed vessel. In one aspect of this embodiment, the container headspace is vented at least once to remove hydrogen chloride and other by-products present in crude molybdenum dichloride dioxide.

Without being bound by theory it is believed that heating low purity MoO₂Cl₂ above its melting point results in decomposition of MoO₂Cl₂ hydrate and other impurities (e.g., hydrogen chloride and water molecules). This does not appear to happen in processes in which MoO₂Cl₂ is not treated above its melting point. During the melting process molybdenum trioxide by-product may settle to the bottom of the vessel allowing better separation from hydrogen chloride by-product. Notably, this approach stands in stark contrast to known procedures for purifying these types of precursors. For example, WO2019/115361 describes a method for purification of various precursors below their melting points. However, it has been unexpectedly observed that performing the melting step is much more efficient and critical for removing residual traces of H₂O and HCl trapped in the solid in order to arrive at ultra-pure MoO₂Cl₂ having previously unattainable purity levels. Indeed, a further advantage of disclosed and claimed process is the ability to filter molten MoO₂Cl₂ to remove insoluble impurities, for example MoO₃ and MoO₂.

Given the above, in one embodiment, the disclosed and claimed process for preparing ultra-pure MoO₂Cl₂ includes the steps of:
a. charging low purity MoO₂Cl₂ into a pressure vessel;
b. heating the vessel to a temperature (ca. from about 180° C. to about 200° C.) sufficient to melt the low purity MoO₂Cl₂;
c. optionally filtering the molten MoO₂Cl₂ to remove insoluble impurities (e.g., MoO₃ and MoO₂);
d. venting the vessel to remove impurities (e.g., HCl gas); and
e. cooling the vessel; and
f. optionally re-venting the vessel.
   In one aspect of this embodiment, steps a-f are repeated until the vessel is filled. In one aspect of this embodiment, one or more of steps a-f is repeated until the vessel is filled. In one aspect of this embodiment, the vessel is constructed of non-corrosive material, such as for example stainless steel, nickel, Monel, Hastelloy, nickel coated stainless steel, etc. In another aspect of this embodiment, the vessel is equipped with at least one valve and is connected to a metal system comprising pressure gage and a second vessel.

In one embodiment, low purity MoO₂Cl₂ powder is charged into a pressure vessel. The vessel with MoO₂Cl₂ is heated from about 180° C. to about 200° C. to completely melt the low purity MoO₂Cl₂. The vessel is cooled to ambient temperature and the vessel headspace is evacuated or purged with inert gas to remove residual hydrogen chloride gas and other potential impurities present in the vapor phase. In one aspect of this embodiment, the vessel is constructed of non-corrosive material, such as for example stainless steel, nickel, Monel, Hastelloy, nickel coated stainless steel, etc. In another aspect of this embodiment, the vessel is equipped with at least one valve and is connected to a metal system comprising pressure gage and a second vessel.

In another embodiment, low purity MoO₂Cl₂ powder is charged into a pressure vessel equipped with at least one valve and is connected to a metal system comprising pressure gage and a second vessel. The vessel with the low purity MoO₂Cl₂ is heated from about 180° C. to about 200° C. C to completely melt MoO₂Cl₂ powder. At this temperature the headspace of the vessel is vented to a second vessel (including inert gas) at a pressure lower compared to the vessel with MoO₂Cl₂. This step may be repeated until MoO₂Cl₂ vessel pressure is within 20% from expected MoO₂Cl₂ vapor pressure at vessel temperature. In one aspect of this embodiment, the vessel is constructed of non-corrosive material, such as for example stainless steel, nickel, Monel, Hastelloy, nickel coated stainless steel, etc. It should be notes that this in this embodiment, the vessel with the low purity MoO₂Cl₂ could alternatively be vented or evacuated at lower temperature.

As noted above, the method can include filtering the molten MoO₂Cl₂ to remove solids insoluble in the melt. Filtration of the melt enables the removal of decomposition by-products and impurities, if any, formed during heating and is not possible when the precursor is treated below the melting point.

### III. Packaged Forms of Ultra-Pure MoO₂Cl₂

As noted above, the disclosed and claimed subject matter relates to packaged forms of the ultra-pure MoO₂Cl₂ with high bulk density and high packing density. Such forms are provided by way of filling containers containing ultra-pure MoO₂Cl₂ that is free and/or substantially free of water and other impurities (at the ppm or lower levels) for use in the electronics/semiconductor industry.

The handling of low bulk density powders with high surface area can easily give rise to moisture contamination. Packaging low bulk density powder with high surface area into containers designed for semiconductor manufacturing can also result in dusting and contamination of container parts with powder. It is also desirable in the semiconductor industry to supply precursor materials in containers with minimal space/footprint requirements due to expensive fab floor space. Thus, containers with small footprint and high packing densities are preferred for chemical delivery cabinets.

In this regard, WO Patent Application Publication No. 2020/021786 describes a process for producing MoO₂Cl₂ that includes sublimating and reaggregating a crude molybdenum oxychloride in a reduced-pressure atmosphere. However, the MoO₂Cl₂ produced by this process had a relatively low bulk density (ca. less than 1.2 g/cm³). Although precursor vaporizing equipment is known (see, e.g., U.S. Patent Application Publication No. 2019/0186003 which provides a vaporizer for vaporizing and delivering vapor to deposition tools) such equipment contains multiple trays and is not suitable for filling the vaporizer with molten solid to achieve optimal (i.e., the highest possible) packing density.

As described above, the ultra-pure MoO₂Cl₂ of the disclosed and claimed subject matter exhibits unexpectedly high bulk densities approaching 3.0 g/cm³. As such, the ultra-pure MoO₂Cl₂ can be provided in packaged forms (e.g., in a canister container where the pressure does not exceed the sum of molybdenum dichloride dioxide partial pressure and partial pressure of inert gas used to backfill canister headspace). As explained above, the bulk density of MoO₂Cl₂ is defined as the mass of MoO₂Cl₂ sample per volume occupied by the sample, expressed in g/cm³. The packing density of a packaged form of the ultra-pure MoO₂Cl₂ is defined as the fraction of the total external volume of the packaged form containing the ultra-pure MoO₂Cl₂, excluding any valve manifold, expressed as kg of MoO₂C₂/liter (external volume). Given the unprecedented high bulk densities the ultra-pure MoO₂Cl₂ packaged forms of the same similarly achieve unprecedented packing densities.

In one embodiment, the packaged forms of the ultra-pure MoO₂Cl₂ have a packing density of about 0.7 kg/L to about 1.5 kg/L of container external volume. In one embodiment, the packaged forms of the ultra-pure MoO₂Cl₂ have a packing density of about 0.7 kg/L to about 1.0 kg/L of container external volume. In one embodiment, the packaged forms of the ultra-pure MoO₂Cl₂ have a packing density of about 1.0 kg/L to about 1.5 kg/L of container external volume.

In one embodiment, the packaged forms of the ultra-pure MoO₂Cl₂ have a packing density of about 0.7 kg/L of container external volume. In one embodiment, the packaged forms of the ultra-pure MoO₂Cl₂ have a packing density of about 0.8 kg/L of container external volume. In one embodiment, the packaged forms of the ultra-pure MoO₂Cl₂ have a packing density of about 0.9 kg/L of container external volume. In one embodiment, the packaged forms of the ultra-pure MoO₂Cl₂ have a packing density of about 1.0 kg/L of container external volume. In one embodiment, the packaged forms of the ultra-pure MoO₂Cl₂ have a packing density of about 1.1 kg/L of container external volume. In one embodiment, the packaged forms of the ultra-pure MoO₂Cl₂ have a packing density of about 1.2 kg/L of container external volume. In one embodiment, the packaged forms of the ultra-pure MoO₂Cl₂ have a packing density of about 1.3 kg/L of container external volume. In one embodiment, the packaged forms of the ultra-pure MoO₂Cl₂ have a packing density of about 1.4 kg/L of container external volume. In one embodiment, the packaged forms of the ultra-pure MoO₂Cl₂ have a packing density of about 1.5 kg/L of container external volume.

In one embodiment, the packaged forms of the ultra-pure MoO₂Cl₂ are provided in a container resembling the shape of a gas cylinder. In one aspect of this embodiment, the container has a height to diameter ratio at least 2/1. In one aspect of this embodiment, the container has a height to diameter ratio at least 3/1. In one aspect of this embodiment, the container has a height to diameter ratio at least 4/1. In one aspect of this embodiment, the container has a height to diameter ratio at least 5/1. In a further aspect of this embodiment, the container is equipped (or can be equipped) with at least one valve and an inlet tube for filling molten ultra-pure MoO₂Cl₂, where the inlet tube resides in the headspace above filled material.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Methods

### ¹H NMR Analysis:

Proton NMR is used as an analytical method for detecting low levels (i.e., 0.1 wt % or lower) of moisture and residual hydrogen atoms in the ultra-pure MoO₂Cl₂. In this methodology, the moisture and total proton content in an ultra-pure MoO₂Cl₂ sample were measured by integration of the water peak of a 5 wt. % ultra-pure MoO₂Cl₂ solution in CD₃CN using ethylene carbonate as an internal standard and blank subtraction.

A 5 mm Wilmad low pressure/vacuum NMR tube was charged with ethylene carbonate (0.008 g) and CD₃CN (1.000 g) under an N₂ atmosphere. The ¹H NMR spectrum was collected using 512 scans with a 1 second relaxation delay on a Bruker Ascend 500 MHZ NMR. Then, MoO₂Cl₂ (0.050 g) was dissolved into the solution under an N₂ atmosphere. Again, the ¹H NMR spectrum was collected under identical conditions as the previous run.

MestReNova software was used to integrate the peak at 4.45 ppm corresponding to the —CH₂— groups in ethylene carbonate and the peak at 2.13 ppm corresponding to H₂O in the blank. In the MoO₂Cl₂ sample, the internal standard at 4.45 ppm and the broad ultra-pure MoO₂Cl₂·xH₂O peak at 5.24 ppm were integrated and blank subtraction was utilized to determine the moisture content in the ultra-pure MoO₂Cl₂ sample. The method detection limit by this method is estimated to be 10 ppm of H₂O in ultra-pure MoO₂Cl₂ which is equivalent to 1.1 ppm of total protons in MoO₂Cl₂.

This analysis was used on all ultra-pure MoO₂Cl₂ samples prepared by the processed disclosed and claimed herein.

### Example 1: Preparation of Ultra-Pure MoO₂Cl₂

A low purity MoO₂Cl₂ sample having low bulk density and high moisture content was analyzed by ¹H NMR method as described above. Moisture in the sample was 709 ppm (equivalent to 78.8 ppm of total residual protons in the low purity MoO₂Cl₂) and the bulk density was 0.3 g/cm3. The low purity MoO₂Cl₂ (5.7 kg) was charged into a 21 L C-22 Hastelloy vessel and heated to 200° C. to completely melt MoO₂Cl₂. The vessel was heated at 200° C. for 24 hours to decompose residual hydrate and to release hydrogen chloride. Thereafter, the vessel was cooled to room temperature and the residual gases were removed under nitrogen purge. An additional 5.0 kg of the low purity MoO₂Cl₂ was then charged on top of the solidified MoO₂Cl₂ melt in the 21 L C-22 Hastelloy vessel and heated to 200° C. to completely melt the low purity MoO₂Cl₂. The vessel was heated at 200° C. for 24 hours to decompose residual hydrate and to release hydrogen chloride. The above steps were repeated two additional times to fill the 21 L container with 20.6 kg of ultra-pure MoO₂Cl₂.

Analysis: The bulk density of the ultra-pure MoO₂Cl₂ was 2.6 g/cm³ as determined by measurement of void volume of the container. A representative sample from the container was analyzed by ¹H NMR as described above and showed the residual moisture in the ultra-pure MoO₂Cl₂ was 126 ppm (equivalent to 14 ppm of total residual protons in the ultra-pure MoO₂Cl₂).

### Example 2: Bulk density of Ultra-Pure MoO₂Cl₂

Low purity MoO₂Cl₂ powder (4.2 g) was charged into a SS316 tube with 10 mm ID. The tube with the low purity MoO₂Cl₂ powder was capped with SS316 VCR caps and heated to 185° C. for 22 hours. The tube was cooled to room temperature and the residual gases were removed with nitrogen purge. The ultra-pure MoO₂Cl₂ formed a solid block at the bottom of the vessel with a 10 mm diameter and 19 mm height. The bulk density of the ultra-pure MoO₂Cl₂ was 2.8 g/cm3. By comparison, the bulk density of the low purity MoO₂Cl₂ described in WO Publication No. 2020/021786 is reported to be around 0.8-1.2 g/cm³.

### Example 3: Container/Vaporizer with High Packing Density of MoO₂Cl₂

A container with 20 kg of low purity MoO₂Cl₂ prepared as demonstrated in Example 1 was heated at 200° C. to completely melt the low purity MoO₂Cl₂. The molten liquid was transferred into a container/vaporizer having external diameter 9.2 inches and 51-inch height (aspect ratio of 5.5), equipped with a valve and an inlet tube. The transfer was repeated at least one time to fill 40 kg of the MoO₂Cl₂ in a 44 L container. During cool down, the container/vaporizer was vented to release excess pressure from hydrogen chloride formed from decomposition of proton-containing species initially present in the low purity MoO₂Cl₂ powder. The samples of ultra-pure MoO₂Cl₂ from the container/vaporizer were collected by vaporization of MoO₂Cl₂ at 160° C.-180° C. and condensing it on a cold surface. The samples were analyzed by ¹H NMR as described above. Residual moisture in the ultra-pure MoO₂Cl₂ was less than about 20 ppm (equivalent to less than about 2.2 ppm of total residual protons in the ultra-pure MoO₂Cl₂).

### Example 4: Preparation of Ultra-Pure MoO₂Cl₂

A low purity MoO₂Cl₂ sample having low bulk density and high moisture content was analyzed by ¹H NMR method as described above. Moisture in the sample was 1074 ppm (equivalent to 119.4 ppm of total residual protons in the low purity MoO₂Cl₂) and the bulk density was 0.3 g/cm3. The low purity MoO₂Cl₂ (6.4 kg) was charged into a 21 L C-22 Hastelloy vessel and heated to 200° C. to completely melt MoO₂Cl₂. The vessel was heated at 200° C. for 12 hours to decompose residual hydrate and to release hydrogen chloride. Thereafter, the vessel was cooled to room temperature and the residual gases were removed under nitrogen purge. An additional 4.0 kg of the low purity MoO₂Cl₂ was then charged on top of the solidified MoO₂Cl₂ melt in the 21 L C-22 Hastelloy vessel and heated to 200° C. to completely melt the low purity MoO₂Cl₂. The vessel was heated at 200° C. for 12 hours to decompose residual hydrate and to release hydrogen chloride. After cooling this 21 L container now contained 10.4 kg of ultra-pure MoO₂Cl₂.

Analysis: The bulk density of the ultra-pure MoO₂Cl₂ was 3.0 g/cm3 as determined by measurement of void volume of the container. A representative sample from the container was analyzed by ¹H NMR as described above and showed the residual moisture in the ultra-pure MoO₂Cl₂ was <15 ppm (equivalent to <2 ppm of total residual protons in the ultra-pure MoO₂Cl₂).

### Example 5: Bulk Density of Ultra-Pure MoO₂Cl₂

Low purity MoO₂Cl₂ powder (10.4 kg) was charged into a 21L C-22 Hastelloy vessel and heated to 200° C. to completely melt MoO₂Cl₂. While at 200° C., 9.8 kg liquid MoO₂Cl₂ was then transferred into an 8.8L C-22 Hastelloy vessel. The 8.8 L vessel was gradually cooled to room temperature by first cooling the bottom and over a period of 4 hours cooling the top of the vessel until the vessel was at ambient temperature. At ambient temperature, the residual gases were removed with vacuum. The ultra-pure MoO₂Cl₂ formed a solid block at the bottom of the vessel with a 222 mm diameter and 85.6 mm height. The bulk density of the ultra-pure MoO₂Cl₂ was 2.96 g/cm³. By comparison, the bulk density of the low purity MoO₂Cl₂ described in WO Publication No. 2020/021786 is reported to be around 0.8-1.2 g/cm³.

### Comparative Example 6: MoO₂Cl₂ Collected from Low Purity MoO₂Cl₂

In this comparative example, the MoO₂Cl₂ was neither purified nor packaged by the disclosed methods. A container with 5.7 kg of low purity MoO₂Cl₂ with a moisture level of 390 ppm (equivalent to 43.4 ppm of total residual protons in the low purity MoO₂Cl₂) was prepared as demonstrated in Example 1 and heated to 150° C., below the melting point of MoO₂Cl₂. A small portion of the hot solid was vapor transferred into an evacuated container with ambient internal surface temperatures over the duration of 30 seconds. The low purity MoO₂Cl₂ at 150° C. was allowed to re-equilibrate for 1.5 hours. A second 30 second vapor transfer was done into the same evacuated container. This 30 second transfer with 1.5-hour re-equilibration holds was repeated 4 more times for a total of 6 hot vapor transfers. Both vessels were cooled to ambient temperature. The material collected in the evacuated receiver, 135 g, had a moisture level of 373 ppm (equivalent to less than about 41.5 ppm of total residual protons in the ultra-pure MoO₂Cl₂). This example demonstrated that Mo202Cl₂ collected from low purity material contained significant amount of moisture (373 ppm) in contrast to Mo₂O₂Cl₂ collected from ultra-pure MoO₂Cl₂ (<20 ppm).

### Example 7: Measurement of HCl Concentration in MoO₂Cl₂ Vapor

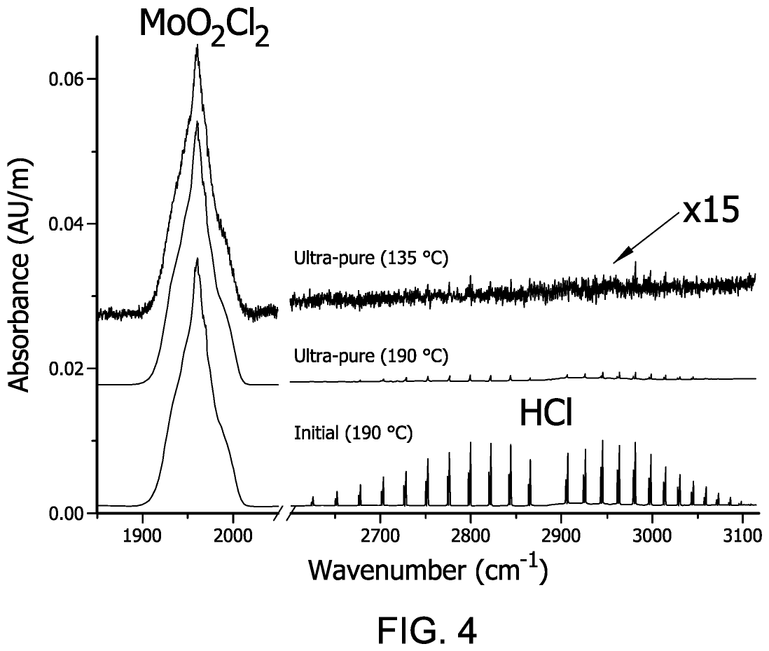

A Hastelloy C22 vessel was filled with MoO₂Cl₂. The vessel was connected to Hastelloy pneumatic valve and SS vacuum manifold. The vessel with MoO₂Cl₂ was heated to 190° C. to melt MoO₂Cl₂ and to release traces of residual HCl into the vapor phase. Residual HCl was purged from the headspace above MoO₂Cl₂ with purified N₂ to obtain ultra-pure MoO₂Cl₂. During the purge N₂ carrier gas containing MoO₂Cl₂ vapor was flowing via 5.33-meter IR cell of the FT-IR spectrometer (MKS Multigas 2030) heated to 150° C. The absorbance of 2799 cm⁻¹ HCl peak in MoO₂Cl₂ reduced from 0.0088 to at least 7.4×10⁻⁴ Absorbance Units/meter HCl at 0.5 cm⁻¹ resolution. FIG. 4 shows the IR spectra of the vapor containing MoO₂Cl₂ and residual HCl where the absorbance of 2799 cm⁻¹ HCl peak in MoO₂Cl₂ is 86.3×10⁻⁴ and 7.4×10⁻⁴ AU/meter. After the purge was completed the vessel with ultra-pure MoO₂Cl₂ was cooled to 135° C. and MoO₂Cl₂ vapor was continuously flowing via 5.33-m IR cell of the FT-IR spectrometer. The absorbance of 2799 cm⁻¹ HCl peak in a gas containing MoO₂Cl₂ was 0.8×10⁻⁴ Absorbance Units/meter. The calculated concentration of HCl in the gas phase was 3.4 ppm. As noted above, FIG. 4 shows that the absorbance of the 2799 cm⁻¹ HCl peak in MoO₂Cl₂ is about 0.8×10⁻⁴ AU/meter.

### SUMMARY

It has been demonstrated that ultra-pure MoO₂Cl₂ can be prepared at purity levels that are nearly 100-fold greater than has previously been reported and that this ultra-pure MoO₂Cl₂ has unexpected properties providing exceptionally high-density packaged forms thereof.

Although the disclosed and claimed subject matter has been described and illustrated with a certain degree of particularity, it is understood that the disclosure has been made only by way of example, and that numerous changes in the conditions and order of steps can be resorted to by those skilled in the art without departing from the spirit and scope of the disclosed and claimed subject matter.

1. Ultra-pure MoO₂Cl₂ having less than about 30 ppm of protons in the physiosorbed or chemisorbed state as measured by ¹H NMR.

2. (canceled)

3. (canceled)

4. The ultra-pure MoO₂Cl₂ of claim 1 having less than 15 ppm of protons in the physiosorbed or chemisorbed state as measured by ¹H NMR.

5-7. (canceled)

8. The ultra-pure MoO₂Cl₂ of claim 1 having less than 3 ppm of protons in the physiosorbed or chemisorbed state as measured by ¹H NMR.

9. (canceled)

10. (canceled)

11. The ultra-pure MoO₂Cl₂ of claim 1 having a residual total content of H₂O of less than about 250 ppm in the physiosorbed or chemisorbed state as measured by ¹H NMR.

12. (canceled)

13. (canceled)

14. The ultra-pure MoO₂Cl₂ of claim 1 having a residual total content of H₂O of less than about 125 ppm in the physiosorbed or chemisorbed state as measured by ¹H NMR.

15. (canceled)

16. (canceled)

17. The ultra-pure MoO₂Cl₂ of claim 1 having a residual total content of H₂O of less than about 50 ppm in the physiosorbed or chemisorbed state as measured by ¹H NMR.

18. (canceled)

19. (canceled)

20. The ultra-pure MoO₂Cl₂ of claim 1 having a residual total content of H₂O of less than about 15 ppm in the physiosorbed or chemisorbed state as measured by ¹H NMR.

21-27. (canceled)

28. The ultra-pure MoO₂Cl₂ of claim 1 having a residual total content of H₂O as determined by ¹H NMR of less than about 0.005 wt % in the physiosorbed or chemisorbed state.

29-33. (canceled)

34. The ultra-pure MoO₂Cl₂ of claim 1 having a residual total content of HCl of less than about 1000 ppm in the physiosorbed or chemisorbed state as measured by ¹H NMR.

35-45. (canceled)

46. The ultra-pure MoO₂Cl₂ of claim 1 having a residual total content of MoO₂Cl₂ x H₂₀ as determined by ¹H NMR of less than about 0.30 wt % in the physiosorbed or chemisorbed state.

47-50. (canceled)

51. The ultra-pure MoO₂Cl₂ of claim 1 having a residual total content of MoO₂Cl₂ x H₂₀ as determined by ¹H NMR of less than about 0.10 wt % in the physiosorbed or chemisorbed state.

52-60. (canceled)

61. The ultra-pure MoO₂Cl₂ of claim 1 having a residual total content of MoO₃ of less than about 0.20 wt % in the physiosorbed or chemisorbed state.

62-65. (canceled)

66. The ultra-pure MoO₂Cl₂ of claim 1, wherein the ultra-pure MoO₂Cl₂ has a bulk density of greater than about 2.0 g/cm³.

67-70. (canceled)

71. The ultra-pure MoO₂Cl₂ of claim 1, wherein the ultra-pure MoO₂Cl₂ has a bulk density of greater than about 2.5 g/cm³.

72-75. (canceled)

76. The ultra-pure MoO₂Cl₂ of claim 1, wherein the ultra-pure MoO₂Cl₂ has a bulk density of greater than about 3.0 g/cm³.

77. A method of preparing the ultra-pure MoO₂Cl₂ of claim 1 comprising the steps of:
a. charging low purity MoO₂Cl₂ into a pressure vessel;
b. heating the vessel to a temperature sufficient to melt the low purity MoO₂Cl₂;
c. optionally filtering the melted MoO₂Cl₂;
d. venting the vessel to remove impurities; and
e. cooling the vessel; and
f. optionally re-venting the vessel.

78. (canceled)

79. The method of claim 77, wherein the step b. heating comprises heating the vessel to a temperature from about 180° C. to about 200° C.

80. A container comprising the ultra-pure MoO₂Cl₂ of claim 1 having a packing density of about 0.7 kg/L to about 1.5 kg/L of container external volume.

81-96. (canceled)

97. A vapor comprising the ultra-pure MoO₂Cl₂ of claim 1 wherein the vapor has less than 300 ppm volume of gaseous HCl.

98-103. (canceled)
